(19) United States
(12) Patent Application Publication
(10) Pub. No.: US 2023/0262911 A1
(43) Pub. Date: Aug. 17, 2023

(54) STAND SYSTEM

(71) Applicant: Otter Products, LLC, Fort Collins, CO (US)

(72) Inventors: RYAN D. SELLDEN, Fort Collins, CO (US); TYLER M. PINTER, Fort Collins, CO (US); DALLAS M. SCAGGS, San Diego, CA (US)

(21) Appl. No.: 18/108,131

(22) Filed: Feb. 10, 2023

Related U.S. Application Data
(60) Provisional application No. 63/310,631, filed on Feb. 16, 2022.

(51) Int. Cl. H05K 5/02; H01R 33/74; H01R 13/62; H01R 33/97; G06F 1/16; F16M 11/04; F16M 11/12; F16M 11/22

(52) U.S. Cl. CPC H05K 5/0234; F16M 11/22; F16M 11/041; F16M 11/125; G06F 1/1632; H01R 13/6205; H01R 33/74; H01R 33/97

(57) ABSTRACT

A stand having a base, an arm attached to the base, an electrical connector, and an adjustable mounting head attached to the arm. The adjustable mounting head includes a plurality of keepers actuated by a button, wherein the plurality of keepers are each configured to engage a respective one of a plurality of receivers on a case for an electronic device such that the case is removably attachable to the adjustable mounting head for holding the case and an installed electronic device on the stand in a preferred orientation. The mounting head includes electrical contacts electrically connected to the electrical connector of the stand and configured to contact an electrical interface of the case for providing the electrical power from the electrical connector of the stand to the installed electronic device through the electrical contacts of the mounting head and through the case.

### CROSS REFERENCE TO RELATED APPLICATIONS

The present application claims priority to U.S. Provisional Pat. Application No. 63/310,631, filed Feb. 16, 2022, which is hereby incorporated by reference in its entirety.

### BACKGROUND

Electronic devices are commonly used for communication, entertainment, data entry, and Internet access, as well as for a variety of other purposes. Examples of electronic devices include smartphones, tablet computers, laptop computers, gaming devices, audio players, video players, cameras, portable computers, two-way radios, GPS receivers, and/or other portable devices. As processing power, screen resolution, and other features increase, these devices are being used for an increasingly wide range of purposes. As these devices become an increasingly important part of peoples’ daily activities, it is desirable to have protective cases that not only protect the electronic devices from damage, but also help flexibly adapt the devices to serve other useful purposes and/or perform other functions. In some situations, personal electronic devices may be used in manners where it is preferred to mount them to a stand or have them held in place in a preferred viewing orientation without the user having to hold the device.

### BRIEF DESCRIPTION OF THE DRAWINGS

FIG. 1 illustrates a stand for an electronic device;

FIG. 2 illustrates a side view of the stand of FIG. 1;

FIG. 3 illustrates a close up view of a mounting head for the stand of FIG. 1;

FIG. 4 illustrates a stand system including the stand of FIG. 1 with a case holding an electronic device attached;

FIG. 5 illustrates an alternate view of the stand system of FIG. 4;

FIG. 6 illustrates another alternate view of the stand system of FIG. 4;

FIG. 7 illustrates the stand system of FIG. 4 with the electronic device removed;

FIG. 8 illustrates the case from FIGS. 4-7 with an interface module;

FIG. 9 illustrates a back side of the case of FIG. 8;

FIG. 10 illustrates the interface module of FIG. 8 without the case;

FIG. 11 illustrates the back of the interface module of FIG. 10;

FIG. 12 illustrates a side view of the interface module of FIG. 10.

### DETAILED DESCRIPTION

As portable electronic devices are used more frequently and for a wider variety of purposes, there is an increasing need for accessories that allow these devices to be used in a wider variety of ways. While portable electronic devices are often held in the user’s hand, there is also an increasing need to have the option of selectively attaching them to a stand or other item. In some situations, a user may wish to keep the electronic device in a particular orientation for a period of time without having to hold it or hold it in position for the entire period. For example, this may occur when a user is watching video content on the electronic device. In other situations, a user may wish to have the device held in an improved or optimized position for other purposes, such as for directing audio in a preferred direction. In yet other situations, the device may be mounted for use by a variety of people, such as in a kiosk, at a point of sale terminal, and/or at a service counter. Consequently, there are opportunities for improved stands and/or holders that hold portable electronic devices in particular positions. In some examples, there may also be a need for these stands to be compatible with one or more protective cases used with the device.

While most of the electronic device cases disclosed herein are described as “protective” cases, the apparatuses and techniques disclosed herein do not necessarily require that the case is protective and could apply to any type of electronic device case, cover, sleeve, sheath, attachment panel, etc. In other examples, the case may be water resistant or waterproof for protecting the electronic device from water or other liquids. In yet other examples, the case may have other characteristics, such as but not limited to, chemical resistance and antimicrobial characteristics. Moreover, while the electronic device cases disclosed herein are generally understood to serve as after-market accessories for original equipment electronic devices (i.e., smartphones, tablet computers, gaming devices, audio players, video players, cameras, portable computers, two-way radios, GPS receivers, other portable devices, etc.), the apparatuses and techniques described herein could also be applied to the actual or primary housings of the original equipment electronic devices themselves.

In one example, a stand system for holding an electronic device in a preferred viewing orientation comprises a case, an interface module, and a stand. The case is configured for directly receiving and removably retaining the electronic device A back surface of the case includes a case mounting interface. The interface module is configured to be removably attached to the case at the case mounting interface. The interface module includes an electrical interface for receiving electrical power and an electrical connector configured to interface to the electronic device when the electronic device is installed in the case to transfer the electrical power from the electrical interface to the installed electronic device through the electrical connector. The stand includes an electrical connector, a base, an arm attached to the base, and a mounting head adjustably attached to the arm. The interface module is removably attachable to the mounting head for holding the case and the installed electronic device in the preferred viewing orientation. The mounting head includes electrical contacts electrically connected to the electrical connector which are configured to contact the electrical interface of the attached interface module for providing the electrical power from the electrical connector of the stand to the installed electronic device through the electrical contacts of the mounting head, through the electrical interface of the interface module, and through the electrical connector of the interface module.

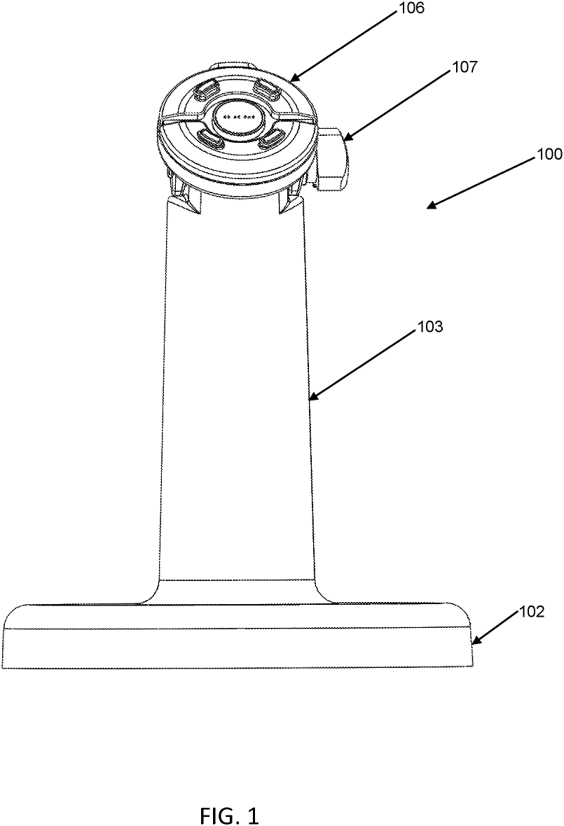

FIG. 1 illustrates a stand 100 configured for use with an electronic device such that a preferred viewing position, viewing angle, or orientation of the electronic device may be maintained without a user having to hold the electronic device and/or having to hold it for extended periods of time. In some examples, stand 100 may also hold the electronic device for use in a multi-user environment such as in a kiosk, as a point of sale terminal, as an information directory terminal, and/or at a customer service counter. Stand 100 may hold the electronic device in a non-horizontal and/or non-vertical orientation even though stand 100 is sitting on a horizontal surface, such as a table. In other examples, stand 100 may also perform a security function by keeping the attached electronic device locked to the stand 100 when used in a public, or semi-public, environment. As described in further detail below, stand 100 may also include charging features.

As illustrated in FIG. 1, stand 100 includes a base 102, an arm 103, and a mounting head 106 which may be adjustable using an adjustment mechanism and temporarily locked in place using knob 107. Base 102 may be a weighted base to reduce the chances of the assembly being tipped over. Based 102 may include attachment features for permanently, or semi-permanently, attaching it to a surface. While one configuration is illustrated in FIG. 1, other configurations are possible. In one example, stand 100 may be configured to be attached to a wall or another non-horizontal surface. Any of the components disclosed herein may have different sizes or shapes.

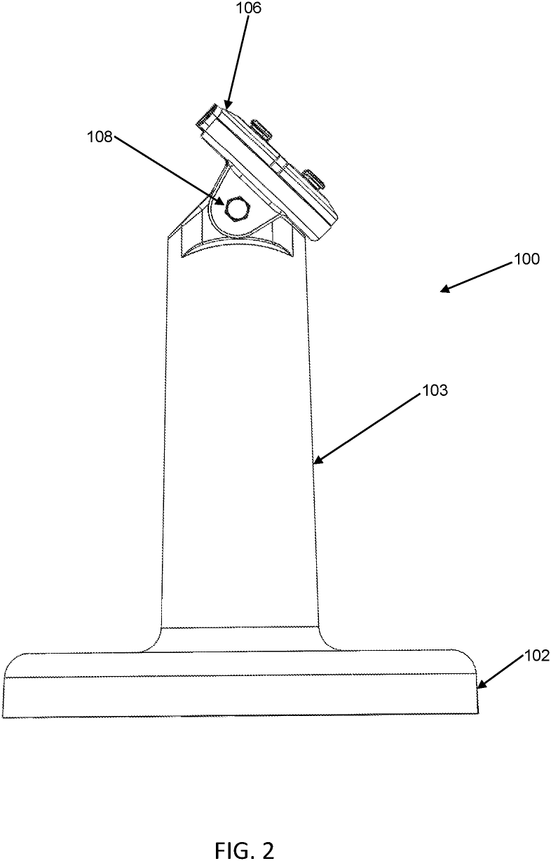

FIG. 2 illustrates a side view of stand 100 of FIG. 1 including a shaft 108 which is attached to knob 107 on the opposite side. Mounting head 106 pivots about the axis of shaft 108 and can be adjusted to a preferred angle or viewing angle by loosening knob 107 and re-tightening once the preferred angle is selected. In some examples, mounting head 106 may be adjustable in two or more axes. In yet another example, mounting head 106 may be attached to arm 103 with a ball and socket, or similar structure, such that it can be adjusted in multiple directions.

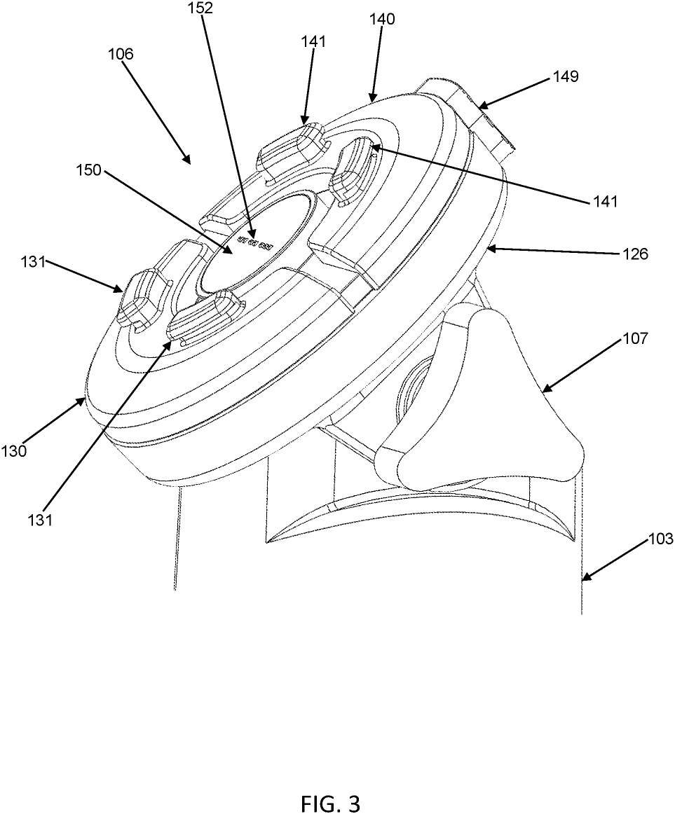

FIG. 3 illustrates a close up view of mounting head 106. Mounting head 106 includes a mounting head base 126, a first interface portion 130, and a second interface portion 140. First interface portion 130 is fixedly attached to or integrated with mounting head base 126 while second interface portion 140 is movably or slidably attached to mounting head base 126. Second interface portion 140 may be biased and/or springloaded such that it tends to relax or return to the position illustrated in FIG. 3 when no external force is applied. First interface portion 130 includes keepers 131 which each have a lip, ledge, tab, overhang, recess, and/or undercut which is used to hold, grasp, or retain another object as described in detail with respect to subsequent figures. Similarly, interface portion 140 includes keepers 141 which each have a lip, ledge, tab, teeth, overhang, recess, and/or undercut which is used to hold, grasp, or retain another object as described in detail with respect to subsequent figures. Keepers 131 and 141 face in different directions from each other. In some cases, any of keepers 131 and/or 141 may also be described as fingers or arcuate fingers. A different number of keepers may be used.

Second interface portion 140 may be selectively actuated or moved such that it temporarily slides closer to first interface portion 130, such as when a user applies force to a release button 149. When this occurs, second interface portion 140, and consequently keepers 141, temporarily move closer to first interface portion 130 and keepers 131. As described in further detail below, this enables keepers 131 and 141 to engage or be inserted into holes, apertures, receivers, and/or under edges of an object. When the applied force is removed from release button 149, second interface portion 140 returns to the illustrated position to hold the object with the lips, ledges, tabs, overhangs, recesses, and/or undercuts of keepers 131 and 141. Mounting head 106 may also include a mounting surface 105 which may contact or interface with the device or object being mounted. In some examples, mounting surface 105 may include one or more electrical contacts 152. In some examples, mounting surface 105 may include one or magnets or metallic elements.

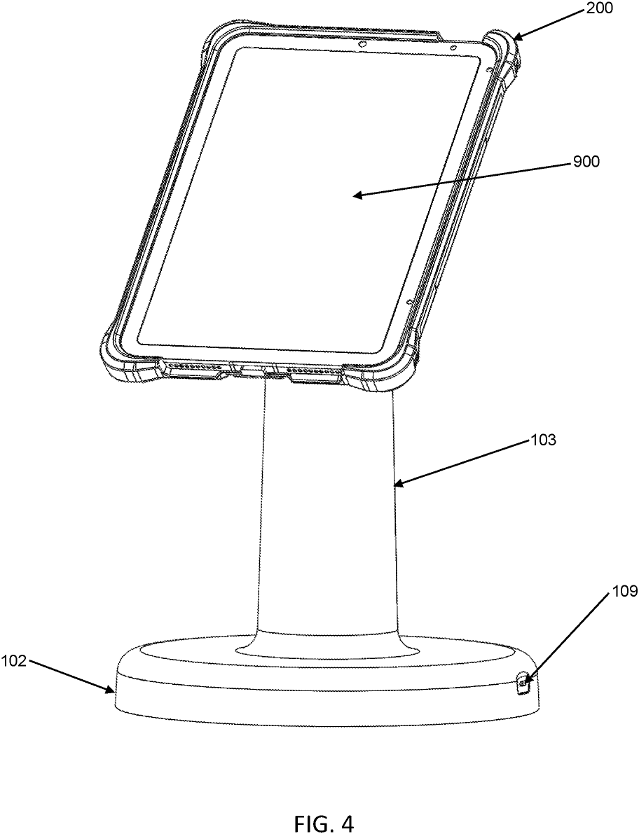

FIG. 4 illustrates a stand system including stand 100 with a case 200 attached and an electronic device 900 installed in case 200. Exemplary protective cases are disclosed in U.S. Pat. Application Publication No. 2017/0017268, the disclosures of which are hereby incorporated by reference in their entirety. Case 200 may include an inner liner and an outer shell. The inner liner may contact the electronic device on any one or more of a back surface, on one or more side surfaces, and/or on a portion of a front surface of the electronic device to retain the electronic device. In some situations, the inner liner may also be referred to as a cushion layer. The inner liner can be made of any suitable material such as an elastomer. The elastomer may be, but is not limited to, a thermoplastic elastomer or silicone rubber. The inner liner may comprise a material that is softer than a material of the outer shell.

The inner liner may be configured to cushion an installed electronic device from external forces, impacts, sudden acceleration, sudden deceleration, and other forces experienced at outer surfaces of case 200. Further, case 200 flexibly holds the electronic device to reduce movement, shifting, or rattling of electronic device 900 within case 200. The inner liner may contain cavities, coring, reliefs, ribs, channels, recesses, a grid pattern, protrusions, and/or other similar features for holding the electronic device in place, for protecting the electronic device, dampening, or distributing force, and/or for potentially reducing the surface area of contact between the inner liner and installed electronic device 900.

The outer shell of case 200 may also be referred to as a structural layer, a frame, a rigid layer, a bottom shell, and/or a shell. The outer shell extends around some or all of the outer surface of the inner liner. The outer shell will typically be manufactured from a material that is harder, more rigid, stiffer, more puncture resistant, more crush resistant, more chemical resistant, and/or more abrasion resistant than the material of the inner liner. The material of the outer shell can be any suitable material such as a thermoplastic polymer or a synthetic polymer. The material can include polycarbonate, nylon, or glass filled nylon. The outer shell can be formed using any suitable process, such as an injection molding process. The back or sides of the outer shell may also include stylistic patterns, images, graphics, and/or colors. In some configurations, case 200 may include two or more different components that are not permanently attached to each other.

FIG. 4 also illustrates connector 109. Connector 109 is an electrical interface for receiving electrical power from an external source through a cord or a cable. Connector 109 may also be used for transmitting and/or receiving electrical data communication signals. Connector 109 may include or may be configured to mate with a standardized electrical plug or connector such as, for example, a USB connector, a mini USB connector, a micro USB connector, an APPLE LIGHTNING® connector, a proprietary electronic connector, and/or an electrical connector of another type. Connector 109 is electrically connected, directly or indirectly through other electronic components, to electrical contacts 152.

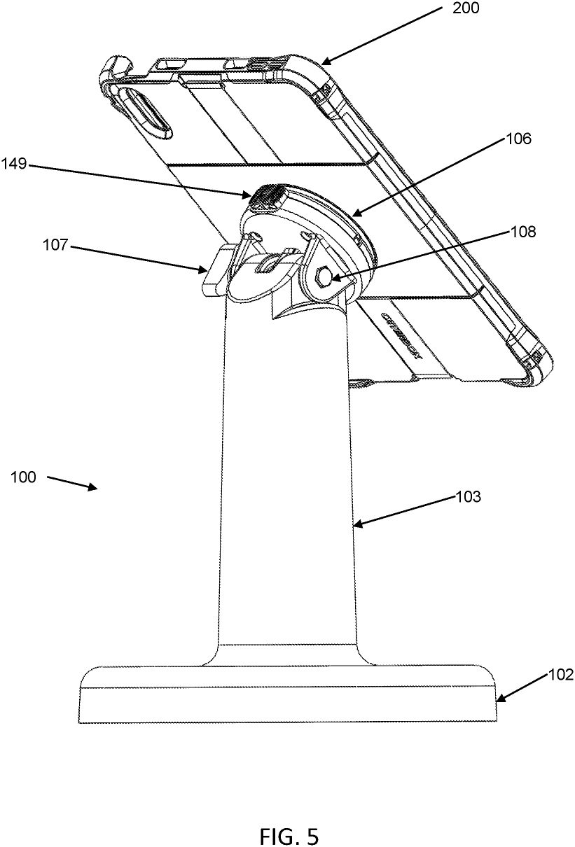

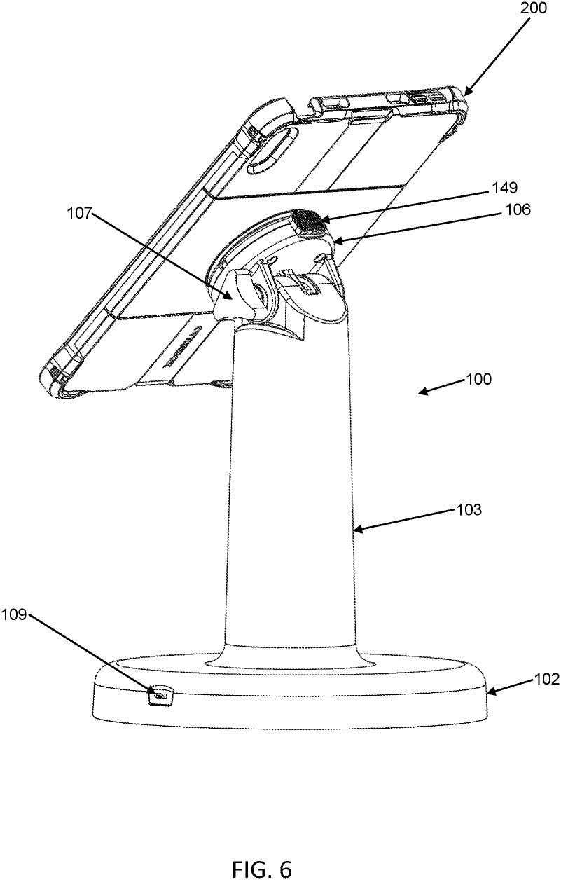

FIG. 5 illustrates an alternate view of the stand system of FIG. 4. A viewing angle or orientation of case 200, and installed electronic device 900, may be adjusted relative to stand 100 by loosening knob 107 and pivoting mounting head 106 about shaft 108. FIG. 6 illustrates another alternate view of the stand system of FIG. 4. While many of the examples herein are described as a system, any subset of the elements or components herein may be claims as an individual apparatus or as a kit including any of the elements or components.

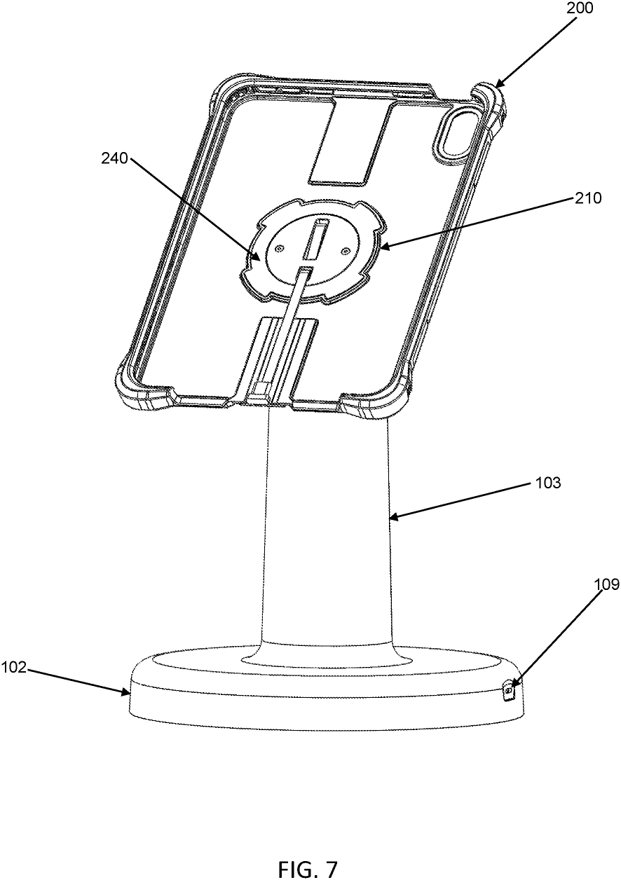

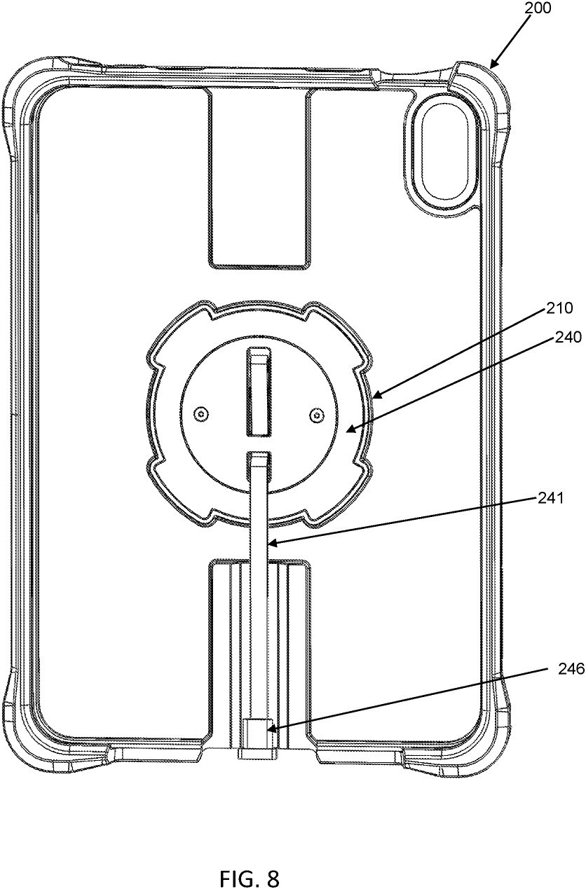

FIG. 7 illustrates the stand system of FIG. 4 without electronic device 900 installed. With electronic device 900 removed, an interface module 240 is visible in case 200. Interface module 240 is removably attached to a case mounting interface 210 of case 200. FIG. 8 illustrates a close up view of the case 200 portion of FIG. 7. Interface module 240 includes an electrical cable 241 which has a connector 246. Connector 246 is configured to engage an electrical connector or charging port of electronic device 900 when electronic device 900 is installed in case 200. In one example, electronic device 900 may be a tablet computer. Connector 246 may include or may be configured to mate with a standardized electrical plug or connector such as, for example, a USB connector, a mini USB connector, a micro USB connector, an APPLE LIGHTNING® connector, a proprietary electronic connector, and/or an electrical connector of another type.

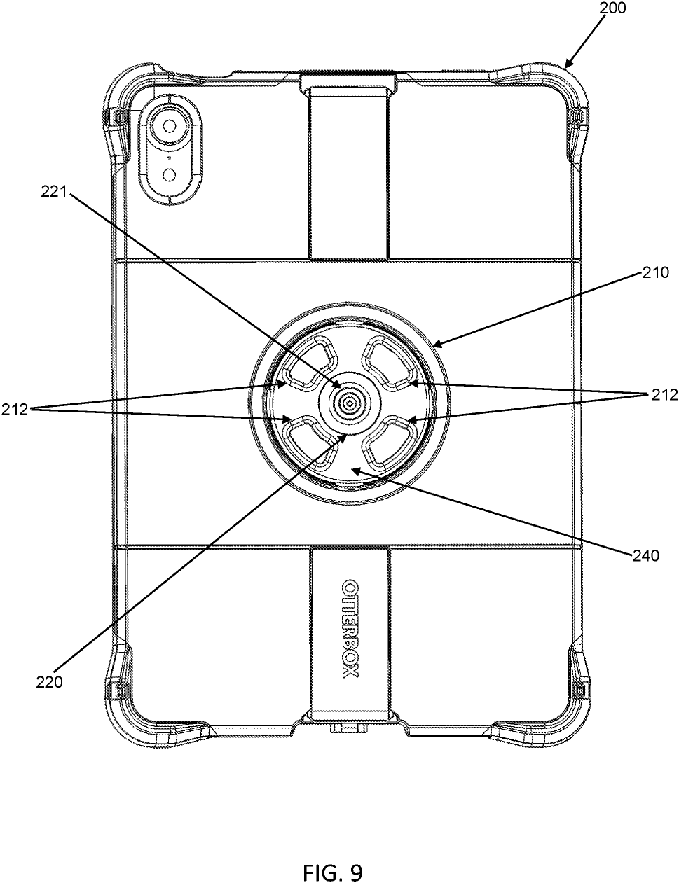

FIG. 9 illustrates a back side of case 200 of FIG. 8 with interface module 240 installed. Interface module 240 includes a plurality of receivers 212 which each include an opening, aperture, cavity, or recess which corresponds to one of keepers 131 and 141 of mounting head 106. When actuated, keepers 131 and 141 engage receivers 212 to hold interface module 240 and, indirectly, case 200. Interface module 240 also includes an interface surface 220 which contacts or engages interface surface 150 of mounting head 106. Interface surface 220 includes electrical contacts 221 for contacting electrical contacts 152 of mounting head 106 for transmitting power and/or data communications between installed electronic device 900 and connector 109. Electrical contacts 221 may be arranged in a circular and/or concentric pattern such that they will each still contact a respective contact of contacts 152 regardless of what orientation case 200 and interface module 240 may have relative to mounting head 106. In other words, the same electrical contacts or connections will be made even if different orientations or angles of case 200 and/or interface module 240 are utilized. Interface surface 220 and/or mounting head 106 may also include a magnet or magnetic element.

Interface module 240 may be removable from case 200 such that case 200 may be attachable to other objects at case mounting interface 210. Alternately, any or all of the elements of interface module 240 may be permanently attached to or integrated into case 200.

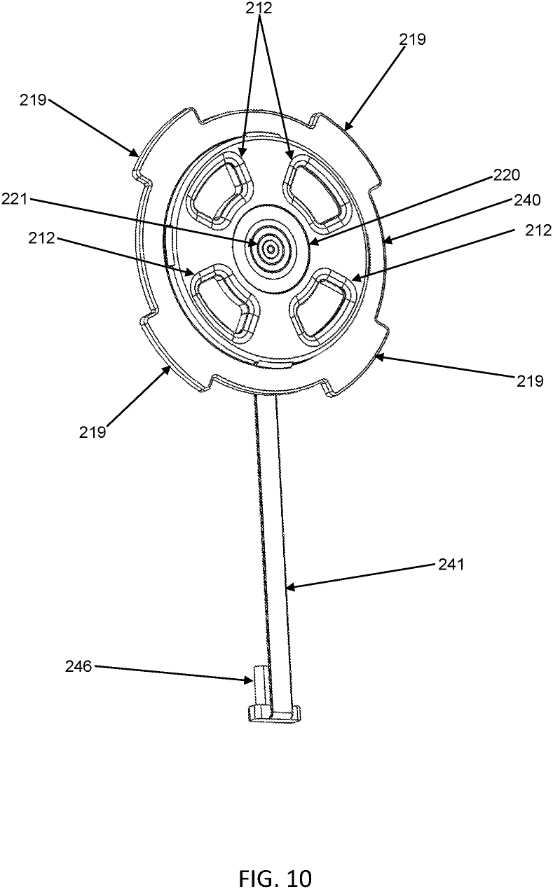

FIG. 10 illustrates interface module 240 removed from case 200. Interface module 240 includes tabs 219 for removably attaching to case 200. Tabs 219 interface with corresponding attachment mechanisms on case 200. Other attachment mechanisms, configurations, and/or quantities are possible. Interface module 240 may be compatible with other cases having different shapes and/or sizes. Interface module 240 may also be compatible with other objects or devices.

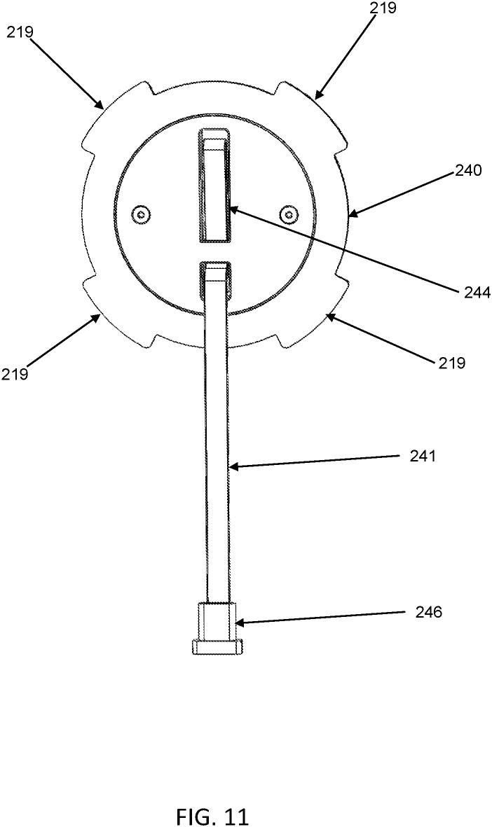

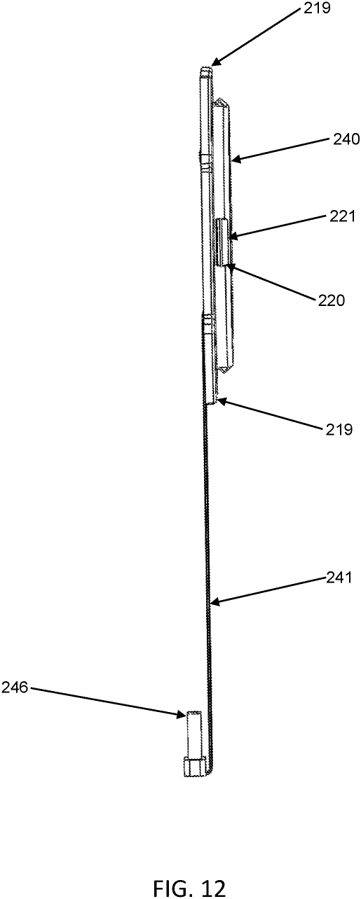

FIG. 11 illustrates a back side of interface module 240 of FIG. 10. As illustrated, cable 241 may also include a cable loop 244 which permits connector 246 to be extended closer or farther from the main body of interface module 240 if needed. This may be beneficial in situations where interface module 240 is used with a different case and/or different electronic device where a distance between case mounting interface 210 and the electrical connector of the installed electronic device differs from other configurations. FIG. 12 illustrates a side view of interface module 240. Case 200 may have features for receiving and/or holding connector 246,

The elements, components, and steps described herein are meant to exemplify some types of possibilities. In no way should the aforementioned examples limit the scope of the invention, as they are only exemplary embodiments.

The phrases “in some embodiments,” “according to some embodiments,” “in the embodiments shown,” “in other embodiments,” “in some examples,” “in other examples,” “in some cases,” “in some situations,” “in one configuration,” “in another configuration,” and the like generally mean that the particular technique, feature, structure, or characteristic following the phrase is included in at least one embodiment of the present invention and/or may be included in more than one embodiment of the present invention. In addition, such phrases do not necessarily refer to the same embodiments or to different embodiments.

The foregoing disclosure has been presented for purposes of illustration and description. Other modifications and variations of the disclosed techniques may be possible in view of the above teachings. The embodiments described in the foregoing disclosure were chosen to explain the principles of the concept and its practical application to enable others skilled in the art to best utilize the invention. It is intended that the claims be construed to include other alternative embodiments of the invention, except as limited by the prior art.

What is claimed is:

1. A stand system for holding an electronic device in a preferred orientation, the system comprising:
a case configured for receiving and removably retaining the electronic device, wherein a back surface of the case includes an interface module which includes an electrical interface for receiving electrical power and an electrical connector configured to interface to the electronic device when the electronic device is installed in the case to transfer the electrical power from the electrical interface of the interface module to the installed electronic device; and
a stand including:
a base;
an arm attached to the base;
an electrical connector; and
a mounting head attached to the arm, wherein the case and the interface module are removably attachable to the mounting head for holding the case and the installed electronic device in the preferred orientation on the stand, wherein the mounting head includes electrical contacts electrically connected to the electrical connector of the stand which are configured to contact the electrical interface of the interface module for providing the electrical power from the electrical connector of the stand to the installed electronic device through the electrical contacts of the mounting head, the electrical interface of the interface module, and the electrical connector of the interface module.

2. The stand system of claim 1 wherein the case includes a case mounting interface and the interface module is configured to removably attach to the case at the case mounting interface.

3. The stand system of claim 2 wherein the case is attachable to other objects at the case mounting interface when the interface module is not attached to the case.

4. The stand system of claim 1 wherein the mounting head is adjustably attached to the arm.

5. The stand system of claim 2 wherein the case and the case mounting interface are configured to be attached to the mounting head in two or more different orientations.

6. The stand system of claim 5 wherein the electrical interface of the case mounting interface is in electrical contact with the electrical contacts of the mounting head in each of the two or more orientations such that the electrical power is conducted from the electrical connector of the stand to the electrical connector of the interface module in each of the two or more orientations.

7. The stand system of claim 6 wherein the electrical interface of the case mounting interface comprises a plurality of electrical conductors arranged as concentric circles.

8. The stand system of claim 1 wherein the interface module includes a plurality of receivers each configured for mechanically engaging a respective one of a plurality of keepers on the mounting head to removably attach the case to the mounting head.

9. The stand system of claim 8 wherein the plurality of keepers are actuated by a spring loaded button on the mounting head.

10. The stand system of claim 9 wherein the plurality of keepers are arranged in a circular pattern and one or more of the keepers moves toward one or more of the other keepers when the release button is actuated.

11. The stand system of claim 8 wherein the interface module include four receivers and the mounting head includes four keepers.

12. The stand system of claim 11 wherein the case is mountable on the mounting head in four orientations.

13. The stand system of claim 1 wherein the case is lockable to the stand.

14. The stand system of claim 1 wherein the mounting head includes a magnet and the interface module includes one of a corresponding magnet and a corresponding metallic element.

15. A stand configured for holding an electronic device in a protective case in a user selected orientation, the stand comprising:
a base;
an electrical connector positioned on the base;
an arm attached to the base; and
an adjustable mounting head attached to the arm, wherein the adjustable mounting head includes a plurality of keepers actuated by a button, wherein the plurality of keepers are each configured to engage a respective one of a plurality of receivers on the protective case, wherein the protective case is removably attachable to the adjustable mounting head for holding the protective case and the installed electronic device in the user selected orientation on the stand when the plurality of keepers engage the plurality of receivers, wherein the mounting head includes electrical contacts electrically connected to the electrical connector of the stand, wherein the electrical contacts of the mounting head are configured to contact an electrical interface of the protective case for providing electrical power from the electrical connector of the stand to the installed electronic device through the electrical contacts of the mounting head and through the protective case.

16. The stand of claim 15 wherein the plurality of keepers is four keepers.

17. The stand of claim 16 wherein the four keepers are arranged in two pairs.

18. The stand of claim 17 wherein a first pair of the two pairs of the keepers is fixed on the mounting head and a second pair of the two pairs of the keepers move relative to the first pair when the button is actuated.

19. The stand of claim 15 further including a cable which interfaces with the electrical connector of the stand.

20. The stand of claim 15 wherein the keepers of the mounting head are configured to engage the receivers of the protective case in a plurality of protective case orientations.
